(19) United States
(12) Patent Application Publication
(10) Pub. No.: US 2007/0025094 A1
(43) Pub. Date: Feb. 1, 2007

(54) Backplane having a wired coupling between card slots

(76) Inventors: Juergen Fischer, Backnang (DE); Harald Geiger, Althuette (DE)

Correspondence Address: KIRSCHSTEIN, OTTINGER, ISRAEL;& SCHIFFMILLER, P.C., 489 FIFTH AVENUE, NEW YORK, NY, 10017, US

(21) Appl. No.: 10/564,688

(22) PCT Filed: Jul. 9, 2004
(86) PCT No.: PCT/EP04/51440

§ 371 Date: Jun. 23, 2006

(30) Foreign Application Priority Data
Jul. 11, 2003 (DE) 103 31 485.7

(51) Int. Cl. H05K 7/10

(52) U.S. Cl. 361/788

(57) ABSTRACT

A backplane for establishing a signal connection between a plurality of cards comprises a support for signaling lines and a plurality of card slots located on the support in a predefined sequence for connecting a card. A plurality of signal-carrier contacts is located at each card slot according to a same pattern. At the card slots, at least two positions of contacts are defined such that a contact at one of these two positions, referred to as the 0-th position, of each card slot that has a successor in the sequence is connected to a contact at the other position of the successor card slot, referred to as the first position, via the backplane.

The present invention relates to a backplane for establishing a signal connection between a plurality of signal processing circuits, referred to subsequently as cards, in a signal processing system, in particular a data processing system and/or communication system.

Such systems often have a modular structure formed of a plurality of cards that are mounted adjacent to one another in a plug-in frame, wherein the signal connection between the cards is formed by a backplane located at the bottom of the frame and comprising a plurality of card slots for connecting a card and a bus by which contacts at corresponding positions of the individual card slots are connected to one another.

For signal transmission on the bus, each card has an address assigned to it. Signals are transmitted on the bus in the form of messages, each of which comprises, besides the payload signal proper, an address that specifies a card (or cards) for which the message is intended, and the individual cards only take account of those messages that comprise the addresses assigned to them. In this way, it is possible to mount the cards at arbitrary card slots of the backplane, without the placement of the individual cards having an influence on the operation of the system.

A condition for a correct evaluation of such a message by a card is that the card be in a state in which it is able to identify a message and the ad-dress contained therein. This cannot be assumed in all cases. In case of a malfunction of a card, e.g. due to a processor crash of a card, it cannot be assumed that the card reacts properly to a received message. Also during the development of a system that uses such cards, it cannot be assumed that each card will react to all conceivable messages that might be sent to it in a desired, predictable manner. It can therefore be desirable to be able to trigger certain functions of a card without there-fore having to transmit a message on the backplane in a format that is compatible with the bus. In particular, in case of safety-relevant functions or a card, i.e. functions that are intended to prevent damages to a card or other components of the system or injury of operating personnel, there is a considerable need to be able to trigger these under all circumstances, even if other functions of the card do not operate properly, be it due to a technical malfunction or because they have not yet been completely developed.

The object of the present invention is to provide a backplane and an assembly comprising a backplane and at least two cards connected to card slots of the backplane, that satisfy this need.

The object is achieved by a backplane having the features of claim 1, and an assembly having the features of claim 6, respectively.

The backplane according to the invention comprises a support for signalling lines and a plurality of card slots arranged in a defined sequence on said support for connecting a card, each of the card slots having a plurality of signal-carrier contacts which are located at each card slot according to a same pattern. It is characterized in that at the card slots at least two positions of contacts are defined Such that a contact at one of these two positions, referred to as the 0-th position, of each card slot that has a successor in said sequence is connected to a contact at the other position of skid successor card slot, referred to as the first position, via the backplane. This connection provides the possibility of signal transmission between a card mounted at a card slot of the back-plane and a second card mounted at the successor or predecessor of this first card slot, which enables one of the two cards—referred to as the controlling card—to send a signal for triggering a function of the other card to this so-called controlled card, whereby this signal can be processed by said controlled card without requiring a recognition of addresses or the like. The only condition which the controlling and controlled cards must meet is that they are located at subsequent card slots of said defined sequence.

Preferably, the contact at the 0-th position of a card slot is not only connected to the first position of a successor, but also to a contact at a i-th position of each i-th successor of the original card slot, wherein i assumes all integer values between 1 and an upper limit n. This measure enables, among others, the use of cards having more than unit width, which cover not only the card slot at which they are contacted, but also one or more predecessor or successor card slots.

Further, preferably the contact at the 0-th position of each card slot is connected to an even number of contacts of other card slots, preferably with a same number of successor and predecessor slots in said defined sequence.

Advantageously, the card slots form one or more groups, in particular in the form of a plug-in frame for mounting in a rack, wherein in each group, the declined sequence of the card slots corresponds to their spatial order.

Preferably, the defined sequence is a cyclical sequence, in which a first card slot of the spatial order of a first one of these groups is successor to a last card slot of the last one of said groups in said defined sequence. Thus, each card slot has a same number of successors and predecessors, respectively, and no card slot is underprivileged from the point of view of possibilities or being controlled from another card slot or controlling a card at another card slot.

The object of the invention is also achieved, according to claim 6, by an assembly comprising a backplane as defined above and at least first and second cards connected to card slots of the backplane, wherein the two cards are connected by a signalling line of the backplane that extends via a contact at the 0-th position of the card slot of the first card, wherein the first card controls a function, in particular a safety function, of the second card by said signalling line.

A particularly important application is the automatic shutdown of a laser source as a safety function in the event that one of said cards is an optical transmitter of an optical communication system.

In order to prevent a card from being undesirably controlled by a plurality of adjacent cards, the second card is preferably adapted to detect if a signalling connection to a first card exists via a j-th contact of its card slot, and to ignore control signals that are present at a i-th contact, with i>j. Alternatively, it is also possible to design a signalling connection between a i-th contact of a card slot and a (i+2)-th contact of a second-next card slot in said defined sequence to be interruptible by mounting a card at the card slot between these two. Thus it is ensured that each controllable card can only be controlled by one adjacent card.

Preferably, a transmission of signals from a controlling first card to adjacent cards is possible in two directions, i.e. to subsequent card slots of the defined sequence as well as to preceding card slots. As will be apparent, all that has been said above concerning the relation between a card slot and its successors may also apply to the relation between said card slot and its predecessors, as is evident from the fact that the defined sequence mentioned above may be replaced by the inverse sequence.

Further features and advantages of the invention become apparent by way of example from the subsequent description of embodiments referring to the appended drawings.

FIG. 1 is a schematic plan view of a backplane according to the invention having a plurality of each slots;

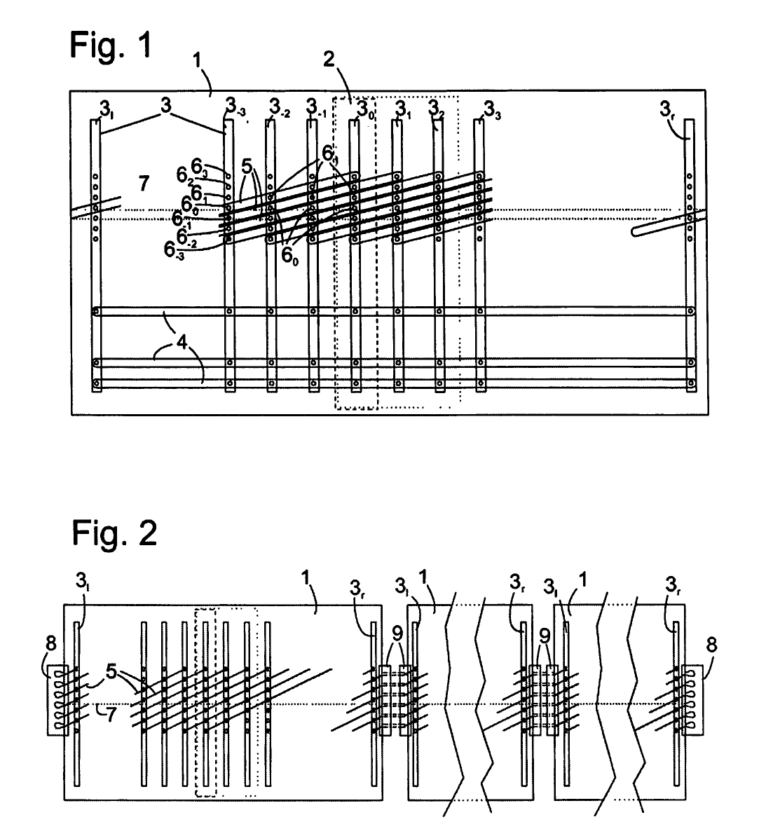

FIG. 2 shows a plurality of backplanes of the type shown in FIG. 1 connected in series for control purposes;

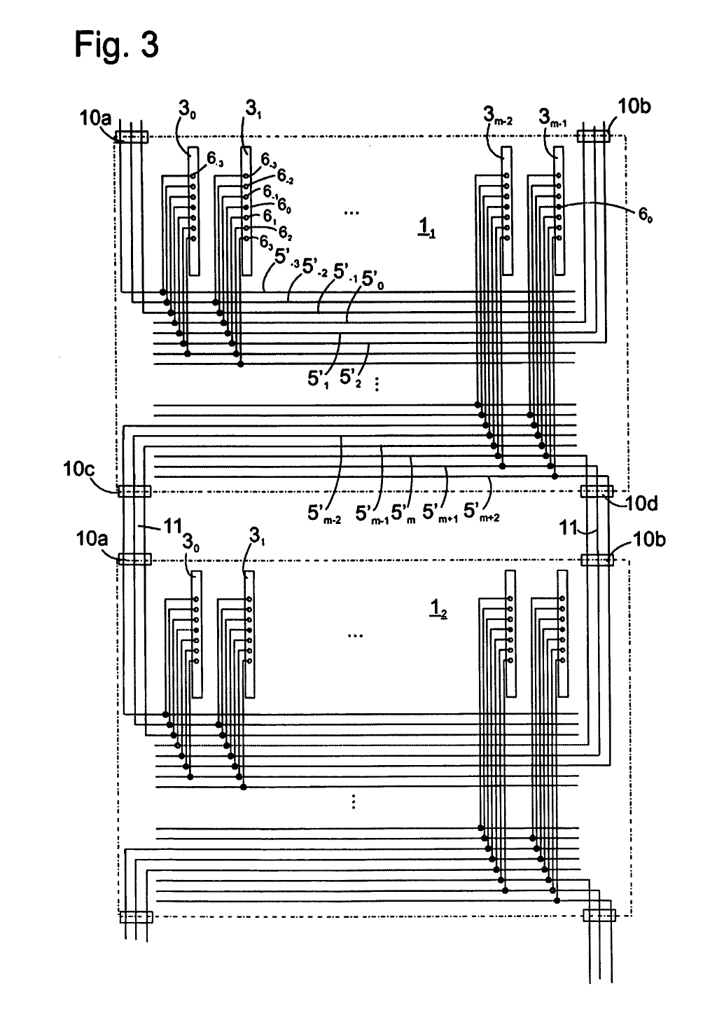

FIG. 3 shows two backplanes mounted in series according to a second embodiment of the invention;

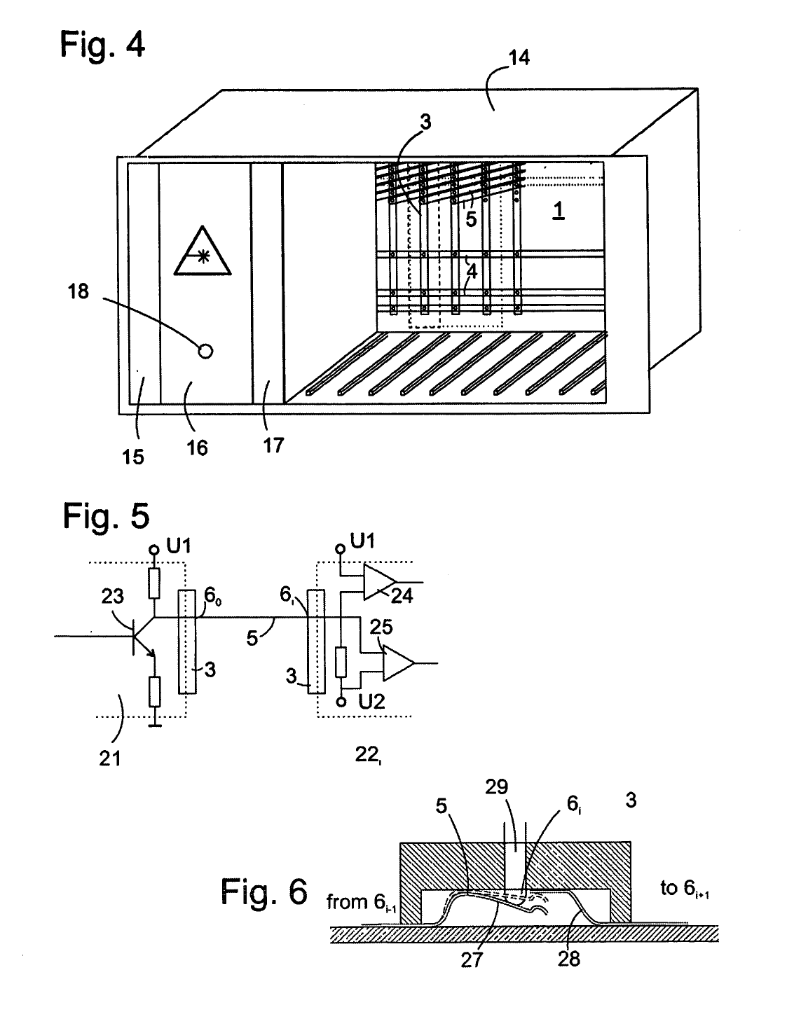

FIG. 4 is a perspective view of a plug-in frame for cards that is equipped with a back-plane according to FIG. 1;

FIG. 5 is an example for a transmitter and receiver stage of two cards connected via the backplane;

FIG. 6 is a schematic section of a connector of the backplane.

FIG. 1 is a schematic plan view of a circuit board which functions as a support for the backplane of the invention. From left to right, the backplane is divided into a plurality of card slots, one of which is highlighted as a dashed rectangle. Each card slot 2 comprises a connector 3, into which a complementary connector of a card (not shown in the Figure) may be inserted. On the circuit board, a bus system for the communication of the cards among each other is formed of a plurality of conductors 4, each of which connects contacts at identical positions of the connectors 3.

There is a second group of conductors 5, each of which connects different contacts 6-3, 6-2, . . . , 60, . . . , 63 of seven mutually adjacent connectors 3. At an individual connector, the contacts 6-3 to 63 are located directly one above the other, so that for the conductors 5 that interconnect these contacts at adjacent connectors 3, the oblique orientation shown in the FIG. Results. One of the contacts, referred to as the 0-th contact 60, is intended for connecting thereto an output of a card which provides a control signal for controlling a function of adjacent cards. A control signal sent by a card at connector 30 thus reaches the three subsequent connectors 31, 32, 33, from left lo right, of the sequence, and the three preceding connectors 3-1, 3-2, 3-3, and is thus capable of controlling a function of cards mounted at these card slots. Inversely, a card mounted at connector 3-1 is capable of controlling cards at connectors 30 to 32 and 3-2 to 3-4.

Conductors 5 that extend across the connector 3l at the left-hand edge of the circuit board 1 are connected to contacts of connector 3r at the right-hand edge of circuit board 1 by conductors 7 extending along the back side of circuit board 1, only one of which is shown in phantom in the Figure. Thus, from the point of view of transmission of control signals between the connectors, the connector 3r functions as a predecessor to connector 3l, i.e. a control signal fed into contact 60 of connector 3l reaches contact 6-1 of connector 3r, and a signal sent at contact 60 of connector 3r is applied to contact 61 of connector 3l. Thus, all connectors from a closed cyclical sequence in which a card mounted at any connector 3 may control up to three adjacent cards in both directions.

FIG. 2 shows an assembly of three circuit boards 1 according to an embodiment that is improved over that of FIG. 1. In FIG. 2, those conductors 5 that cross one of the edges of their circuit board 1 are not through-contacted to a conductor 7 at the back side of circuit board 1, as in FIG. 1, but both the conductors 7 and the conductors 5 that cross the edge end at contact pads at the edge of circuit board 1, onto which a connector 8, 9 may be plugged. Incidentally the two connectors referred to by 8 in the Figure are only for connecting conductors 5, 7 at front and back sides of circuit board 1, whereas the connectors 9 that are connected pairwise, e.g. by a flat ribbon cable, are intended for interconnecting conductors 5 and 7 at mutually corresponding positions of adjacent circuit boards 1. In this way, a connector 3l at the left-hand edge of the central circuit board 1 becomes successor to a connector 3r at the right-hand edge of the left-hand circuit board 1, and a connector 3r at the right-hand edge of the central circuit board 1 becomes predecessor to a connector 3l at the left-hand edge of the right-hand circuit board 1, and the right-hand connector 3r of the right-hand circuit board 1 becomes predecessor to the left-hand connector 3l of the left-hand circuit board 1 via the connector 8 plugged onto right-hand edge of said circuit board and via the connectors 9 that interconnect the back side conductors 7.

Obviously, in principle an arbitrary number of circuit boards 1 may thus be connected in series or be connected to form a ring.

In most practical applications, if several plug-in frames for cards are required, these are not placed besides each other but one above the other. FIG. 3 shows a schematic layout of a backplane according to the invention, in which the layout of the conductors is specifically adapted to these requirements. Herein, the conductors of the bus system have been left out for the sake of simplicity. The Figure shows two circuit boards 11, 12 of identical design. Each circuit board 11, 12 has a total of m+n conductors 5′ that extend essentially across the whole width of the circuit board 1, m being the number of connectors 3 of the backplane and n being the number predecessors or successors, respectively (here n=3) to which each connector 3 is connected via the conductors 5′.

The connectors are referred to as 30 to 3m−1, and the i-th contact 6i, i=−3 . . . , +3 of a connector 3j, j=0, . . . , m−1 is connected to conductor 5′i+j.

Among the conductors 5′-3, 5′-2, . . . , 5′m+2, the conductors 5′-3, 5′-2, 5′-1 are led to a connector 10a at an upper left corner of circuit board 11; conductors 5′0, 5′1, 5′2 are led to a connector 10b at an upper right corner of circuit board 11; conductors 5′m−3, 5′m−2, 5′m−1 lead to a connector 10c at a lower left corner, and the conductors 5′m, 5′m+1, 5′m+2 lead to a connector 10d at a lower right corner of circuit board 11. The connectors 10c, 10d are connected to connectors 10a, 10b, of the circuit board 12 located underneath by cables 11. This enables a card at the last connector 3m−1 of circuit board 1I to transmit, by its contact 60 leading to conductor 5′m−1, control signals not only to the predecessor card slots 3m−2, 3m−3, 3m−4 on circuit board 11, but also, as can easily be recognized by tracing the conductors in the FIG., to connectors 30, 31, 32 of circuit board 12. These thus become successors to connector 3m−1 of circuit board 11 by means of the cables 11 that interconnect the circuit boards.

According to the pattern described above, in principle, an arbitrary number of circuit boards may be connected in series. If the connectors 10c, 10d of the last such circuit board are connected to connectors 10a, 10b, respectively, of circuit board 11, a cyclical sequence of the connectors 3 results, in which e.g. the connector 30 of circuit board 11 has predecessors on said last circuit board, which may be controlled by a card at card slot 31 or are capable of controlling this card.

FIG. 4 is a perspective view of a plug-in lame 14, an essentially brick-shaped cabinet having an open front side and a rear side at which a backplane is mounted as described below in detail. In the cavity of plug-in frame 14, in front of the backplane, a plurality of cards 15, 16, 17 is placed guided on rails. Each of these cards carries at its rear side a connector (not shown) that is compatible to a connector 3 of the backplane. The cards may have different widths, for instance in FIG. 4 the cards 15, 17 have a width corresponding to a distance between two connectors 3, and the card 16 is three times as wide as the cards 15, 17, so that it covers three connectors 3 of the backplane but is in contact with only one of these. Within the context of the present invention, the tasks of the cards 15, 16, 17 can be quite arbitrary. It must only be distinguished between a first group of cards which are intended to control a function of another card and are therefore capable of outputting a control signal at contact 60 of their plug-in location, and a second group of cards which have functions adapted to be controlled by a card of the first group, i.e. that are capable of receiving a control signal at one of contacts 6-3, 6-2, 6-1, 61, 62, 63. As an example for a card of the second group, card 16 may be taken, which is a laser transmitter module for an optical telecommunication system, and which has a coupling 18 for connecting an optical fiber. If no optical fiber is present at this coupling 18, laser radiation generated by the transmitter module may escape at this coupling 18 and may injure persons. In order to prevent this, card 16 has a card 17 associated to it, the purpose of which is to monitor the proper presence of the optical fiber at coupling 18 and to prevent the laser emission by card 16 if it cannot be properly detected that the optical fiber is connected.

In order to achieve an as high degree of flexibility as possible for the placement of cards in the frame 14, it is desirable to insure that a controlling card such as card 17 can only control one adjacent controllable card such as card 16. If the cards have different widths, as in the case considered here, the number n of predecessor and successor connectors that can be reached by a control signal must be adapted to the maximum width of the card. That is, in order to be able to control the card 16 having three times the unit width from a plug-in location adjacent to the right or to the left, n must at least equal 3.

However, a problem results if technical progress allows to replace e.g. card 16 by a card of unit width. Then, two plug-in locations are freed, which are also subject to control by the card 17 if no specific measures are taken. Possibilities for preventing undesirable control of cards subsequently mounted in these freed plug-in locations are described by means of FIGS. 5 and 6.

FIG. 5 shows an electronic solution of the problem. According to this solution, a controlling card has an output circuit 21 connected to the contact 60 of the connector 3 of this card, and controlled cards have input circuits 21i at all contacts 6i, i=1, 2, . . . , n. Controlled cards have a high resistivity at their contact 60. The output circuit 21 of the con-trolling card provides, according to the level sup-plied to its transistor 23, either a voltage level close to a supply voltage U1 or close to mass to conductor 5. The input circuit 22 recognizes by means of′ first comparator 24 which level is output by output circuit 21. A second supply voltage U2 the sign of which is opposite to that of U1, is connected to conductor 5 by a high bias resistor 25 and thus has only little influence on its voltage level. However, if no output circuit 21 is connected to conductor 5, it assumes voltage level U2. This is recognized by a second comparator of input circuit 22.

Let us now consider the case that a controlling curd is mounted at an arbitrary connector 3j and a controlled card is mounted at a second next successor connector 3j+2. If the intermediate connector 3j+1 is free or is occupied by another controlled card, the contact 61 of the controlled card is at U2, and the controlled card at connector 3j+1 recognizes that no controlling signal can come from this plug-in location. In this case, it checks the potential at the subsequent contact 62. Since this one is connected to the controlling card, it is either at mass or at U1. The controlled card carries out the action defined by the level at contact 62 and ignores signals that may be present at contact 63. The level at this contact would only be evaluated if both lower index contacts 61, 62 were found not to be connected to a controlling card. In this way, the controlled card is always controlled by just one controlling card, namely the closest adjacent one.

A similar effect can be achieved mechanically by the solution depicted in FIG. 6. It shows a schematic section through a connector 3 at the level of a contact 6i, i>0. The conductor 5 at the level of connector 3 is formed by a contact spring 27 connected to contact 6i−1 of the predecessor plug-in location, and a contact plate 28, which is connected to contact 6i+1 of a successor plug-in location. The contact spring 27 extends across a bore of the connector, into which a pin 29 of a card mounted at this connector can be inserted. The pin 29 elastically urges the contact spring 27 from a position shown in phantom, in which it touches the contact plate 28, into a position shown in solid outline, in which this contact is cancelled. Thus, each card at a successor of the shown connector 3 is cut off from control signals that conic from a predecessor connector, i.e. each controlling card can only control immediately adjacent controlled cards, but not second-next neighbors.

1-10. (canceled)

11. A backplane for establishing a signal connection between a plurality of cards, comprising: a support for signaling lines and a plurality of card slots located on said support in a predefined sequence for connecting the cards, each of the card slots having a plurality of signal-carrier contacts which are located at each card slot according to a same pattern, at least two positions of contacts being defined at the card slots such that a contact at one of these two positions of each card slot that has a successor in said sequence is connected to a contact at the other position of the successor card slot via the backplane.

12. The backplane of claim 11, in that the contact at said one position of each card slot having an n-th successor in said sequence, n being an integer and larger than one, is in communicating connection with a contact at an i-th position of an i-th successor for all i=1, . . . , n.

13. The backplane of claim 12, in that the contact at said one position of each card slot is in communicating connection with an even number of contacts of other card slots.

14. The backplane according to claim 11, in that the card slots form one or more groups and are located spatially adjacent within each group, and in that the defined sequence in each group corresponds to the spatial order of the card slots.

15. The backplane of claim 14, in that the defined sequence is a cyclical sequence in which a first card slot of the spatial order of a first one of said groups is successor to a last card slot of a last one of said groups.

16. An assembly comprising: a backplane and at least first and second cards connected to card slots of said backplane, the first and second cards being connected by a signal line of the backplane, the signal line extending via a contact at a 0-th position of the card slot of the first card, and the first card controlling a safety function of the second card by said signal line.

17. The assembly of claim 16, in that the safety function is an automatic demagnetization of a laser source of the second card.

18. The assembly of claim 16, in that the second card is adapted to detect if a signal connection to the first card exists via a j-th contact of its slot and to ignore control signals appearing at an i-th contact, where i is greater than j.

19. The assembly of claim 16, in that a signal connection between an i-th contact of a card slot and an (i+2)-th contact of a succeeding card slot of said defined sequence is interruptible by mounting a card in a card slot located between said two card slots.

20. The assembly according to claim 19, in that the first card is connected by said signal line to one contact, referred to as the i-th contact, of the i-th successor of its own card slot and with a contact referred to as the (-i)-th contact, of the i-th predecessor of its own card slot for all i=1, . . . , n.
